(19) United States
(12) Patent Application Publication
(10) Pub. No.: US 2003/0080394 A1
(43) Pub. Date: May 1, 2003

(54) Control of dopant diffusion from polysilicon emitters in bipolar integrated circuits

(76) Inventors: Jeffrey A. Babcock, Richardson, TX (US); Angelo Pinto, Allen, TX (US); Leland Swanson, McKinney, TX (US); Scott G. Balster, Munich (DE); Gregory E. Howard, Dallas, TX (US); Alfred Hausler, Freising (DE)

Correspondence Address: TEXAS INSTRUMENTS INCORPORATED, P O BOX 655474, M/S 3999, DALLAS, TX, 75265

(21) Appl. No.: 10/283,492

(22) Filed: Oct. 30, 2002

Related U.S. Application Data
(60) Provisional application No. 60/334,710, filed on Oct. 31, 2001.

(51) Int. Cl. H01L 21/331; H01L 21/8222; H01L 21/8228; H01L 29/00

(52) U.S. Cl. 257/555; 438/311; 438/322; 438/547

(57) ABSTRACT

An integrated circuit and a method of fabricating the same are disclosed. Complementary bipolar transistors (20p, 20n) are fabricated as vertical bipolar transistors. The emitter polysilicon (35), which is in contact with the underlying single-crystal base material, is doped with a dopant for the appropriate device conductivity type, and also with a diffusion retardant, such as elemental carbon, SiGeC, nitrogen, and the like. The diffusion retardant prevents the dopant from diffusing too fast from the emitter polysilicon (35). Device matching and balance is facilitated, especially for complementary technologies.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

This invention is in the field of semiconductor integrated circuits, and is more specifically directed to the formation of doped emitter junctions in bipolar transistors in such circuits.

Modern bipolar integrated circuits now typically use vertical bipolar transistors as their active elements. These transistors are vertical in the sense that the active base and emitter regions overlie the collector region, with collector-emitter current traveling through the base in substantially a vertical orientation relative to the plane of the surface of the integrated circuit at which the transistor resides. The characteristics of the emitter-base junction, and of the emitter region itself, are of critical importance in the device performance.

In these modern bipolar transistors, the emitter region is generally formed by diffusion of dopant from a doped polysilicon emitter electrode, through an opening in an insulating layer, and into a single-crystal silicon base region of the opposite conductivity type. FIG. 1a illustrates, in cross-section, a conventional PNP bipolar transistor device, formed in this example in a silicon-on-insulator (SOI) technology. Buried oxide layer 4 is disposed over single-crystal silicon handle wafer 2, and under thin film (single-crystal) silicon layer 6. This SOI structure may be formed by way of any one of the known conventional techniques, including wafer bonding, implanted oxygen (SIMOX), and the like. Epitaxial layer 8 is disposed over thin film silicon layer 6, and extends toward the surface of the structure as shown. Isolation structures in transistor 10 include trench isolation oxide structures 9, formed by etching into (and possibly through) epitaxial layer 8 and thin film silicon layer 6, as desired. The active portions of transistor 10p include the collector region formed in epitaxial layer 8 (i.e., the subcollector), base layer 11, and polycrystalline emitter electrode 15. Emitter contact E, base contacts B and collector contact C make electrical contact to the device by way of a metal contact to tungsten plugs 16e, 16b, 16c, respectively. A heavily-doped portion of thin film silicon layer 6, and also a lower portion of epitaxial layer 8, provides a conductive lateral path for collector current to tungsten plug 16c. Diffusion of dopant from polysilicon emitter electrode 15 into base layer 11 forms the active emitter of the device, at which location the bipolar transistor action takes place.

FIG. 1b illustrates, in a magnified manner, the diffusion of boron dopant from emitter electrode into base layer 11. As shown in FIG. 1b, a lightly-doped region 17 is in place over base layer 11. Emitter polysilicon 15, which is heavily doped with boron, is insulated from region 17 by oxide layer 19, with the exception of emitter window W, through which emitter polysilicon 15 extends to make physical contact with region 17. Exposure of the device to high temperature, either over an extended time or by way of a rapid thermal anneal (RTA), causes boron to diffuse from polysilicon emitter electrode 15 into and through region 17, forming the active emitter of the transistor.

As is well known in the art, the dopant gradient from emitter to base and to collector largely determines the gain and other characteristics of the bipolar transistor. Variations in the diffusion profile of the emitter thus result in significant changes in device performance. Control of the emitter diffusion is therefore an important process requirement for high performance bipolar technologies.

In advanced bipolar technologies, the transistors have been scaled down to extremely small devices, both from the standpoint of chip area and also in regard to junction depth. As a result, control of the diffusion of dopant from the emitter polysilicon into the base region, while always an important step, has become more difficult considering the small sizes and junction depths now being used.

Complementary device technologies, in which transistors of complementary conductivity types are formed in the same integrated circuit, have become more important in recent years, especially considering the explosion in the use of battery-powered digital systems for computers, wireless telephones, personal digital assistants, and the like. In the metal-oxide-semiconductor (MOS) field, the complementary technology is referred to as CMOS. This complementary trend has also now reached the bipolar regime, with complementary bipolar, and complementary hybrid bipolar and CMOS (CBiCMOS), technologies now being developed and used. An important factor in the success of a complementary technology is the extent to which the characteristics of the complementary devices, such as NPN and PNP transistors, match one another.

As mentioned above, emitter diffusion control is of critical importance in modern high performance bipolar technologies. In the complementary bipolar context, however, the control of emitter diffusion is made extremely difficult because two emitter dopant species (n-type and p-type) must be considered. As is fundamental in the art, the diffusion of dopant occurs upon the exposure of the integrated circuit structure to elevated temperature over time. Complementary devices on the same integrated circuit are of course subjected to the same time and temperature profile. However, the diffusion rate of p-type dopant (e.g., boron) is significantly different from that of n-type dopants (e.g., phosphorous, arsenic, antimony). For example, the diffusion rate of boron is at least ten times that of arsenic. Assuming similar dopant concentrations in the emitter polysilicon and base regions, the emitters of the NPN and PNP devices will have significantly different physical profiles from one another when subjected to the same diffusion conditions (time and temperature).

Conventional manufacturing processes for complementary bipolar technologies have addressed this issue by controlling the extent to which the structures are exposed to high temperatures after formation of the emitter polysilicon. By reducing the high temperature exposure of the structures, the emitter dopant in both of the NPN and PNP devices diffuses less, and therefore the difference in diffusion profile is minimized. However, the restriction of high temperature processes, referred to as the “thermal budget”, places significant constraints on the ability to fabricate the remainder of the integrated circuit in the optimal manner. In addition, this differential diffusion has also required separate emitter anneals to be performed for the NPN and PNP devices, with one anneal (typically an RTA) performed after the formation of one emitter electrode type and before the formation of the other, followed by a second RTA received by both device types. However, this approach drives up manufacturing costs, and results in tradeoffs between complementary emitter matching and other device parameters.

### BRIEF SUMMARY OF THE INVENTION

It is therefore an object of the present invention to provide a method of fabricating a bipolar integrated circuit, and an integrated circuit device so fabricated, in which the diffusion of emitter dopant can be readily controlled.

It is a further object of this invention to provide such a method and device in which the diffusion of both conductivity types of dopant can be controlled to more closely match one another.

It is a further object of this invention to provide such a method and device in which constraints on the thermal budget for processes after formation of the emitter are relaxed.

It is a further object of this invention to provide such a method and device which is also compatible with the formation of MOS transistors in the same integrated circuit.

It is a further object of this invention to provide such a method and device in which the emitter resistance is reduced by the removal of native oxides at the emitter-base interface.

Other objects and advantages of the present invention will be apparent to those of ordinary skill in the art having reference to the following specification together with its drawings.

The present invention may be implemented by doping the emitter polysilicon electrodes with their corresponding emitter dopant in combination with a diffusion retardant, such as a carbon-bearing species or nitrogen. The retardant slows the diffusion rate of boron and of many n-type dopants, reducing the sensitivity of the emitter diffusion to time and temperature and thereby relaxing the thermal budget of subsequent processes. This effect improves the matching of complementary bipolar transistors with one another, and is compatible with the formation of MOS transistors in the same device.

According to another aspect of the invention, the carbon-bearing species both retards the diffusion of boron (p-type dopant) and enhances the diffusion of arsenic (n-type dopant), which otherwise diffuses more slowly than boron. Closely-matched emitters are formed from boron-doped and arsenic-doped polysilicon emitters that are doped with a carbon-bearing species.

### BRIEF DESCRIPTION OF THE SEVERAL VIEWS OF THE DRAWING

FIGS. 1a and 1b are cross-sectional views of a conventional bipolar transistor.

FIGS. 2a through 2f are cross-sectional views of bipolar transistors constructed according to the preferred embodiments of the invention.

FIG. 3 is a cross-sectional view of a metal-oxide-semiconductor (MOS) transistor constructed according to the preferred embodiments of the invention.

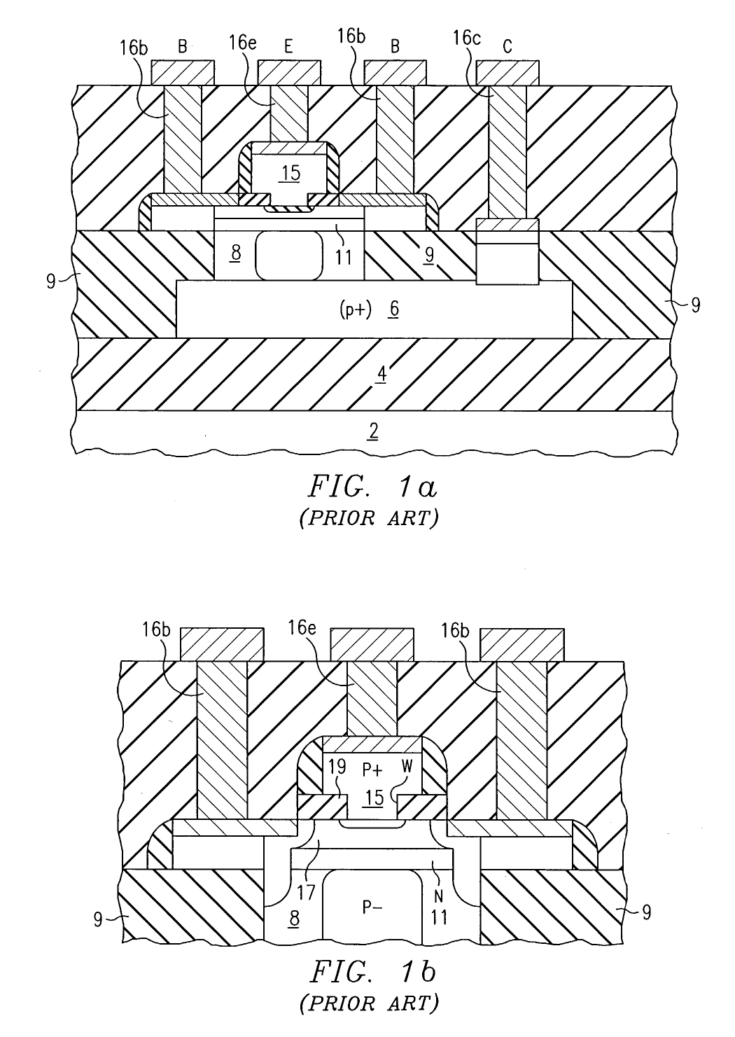

### DETAILED DESCRIPTION OF THE INVENTION

The present invention will now be described in connection with its preferred embodiments. These exemplary embodiments are directed to the fabrication of bipolar junction transistors in a silicon-on-insulator (SOI) structure. It will be appreciated by those skilled in the art having reference to this specification that the present invention may be used to form either PNP or NPN transistors, or both as may be used in a complementary bipolar or BiCMOS technology, as well as used to form other alternative structures. In addition, while this invention is particularly beneficial as applied to SOI structures, it is also contemplated that this invention may also be utilized in bulk integrated circuit devices, where no buried insulator layer is present. Furthermore, while these embodiments are silicon or SiGe NPN and PNP bipolar transistors, it is contemplated that the present invention will be equally applicable to emerging bipolar technologies such as SiGeC (silicon-germanium-carbon) and SiC bipolar technologies It is therefore to be understood that these and other alternatives to the embodiments described below are contemplated to be within the scope of the invention as claimed.

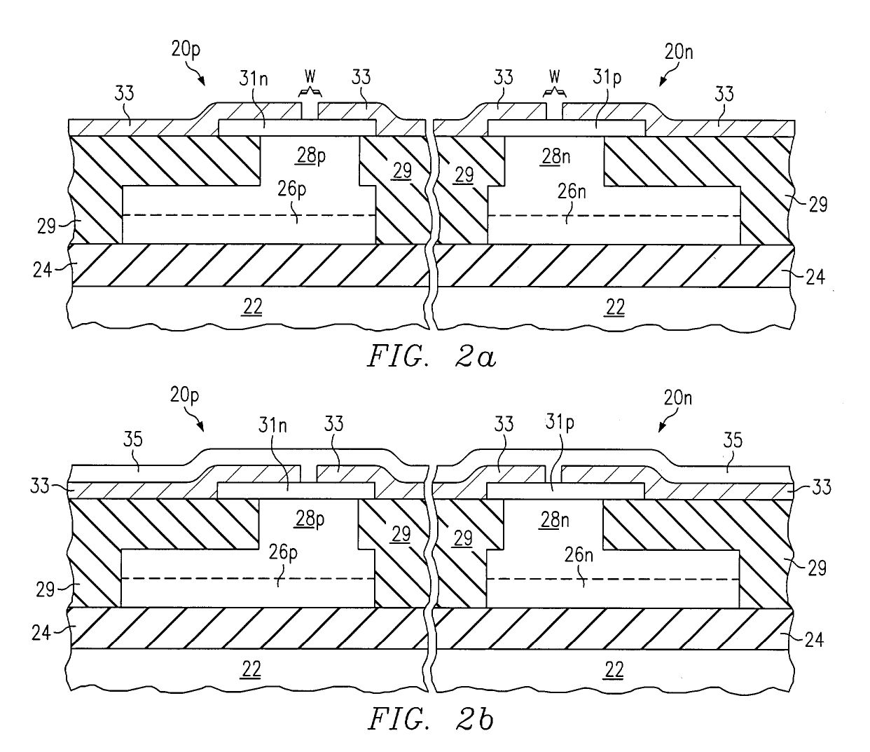

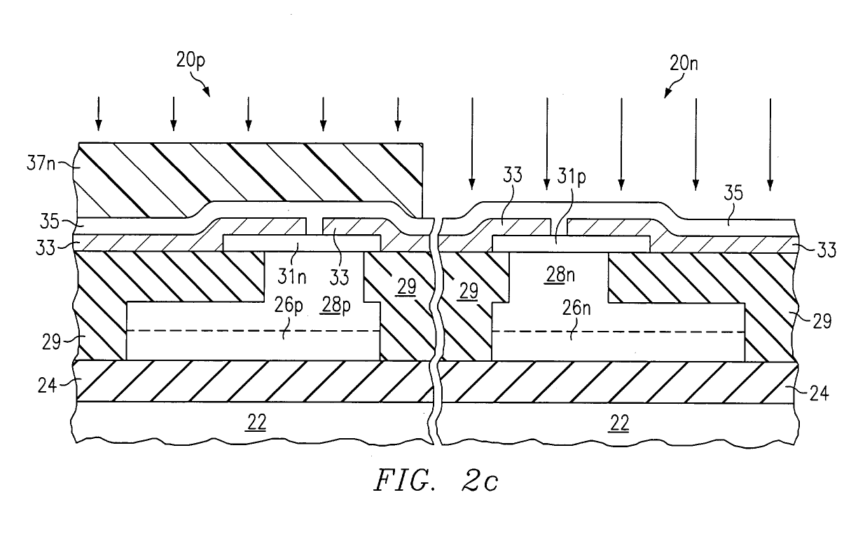

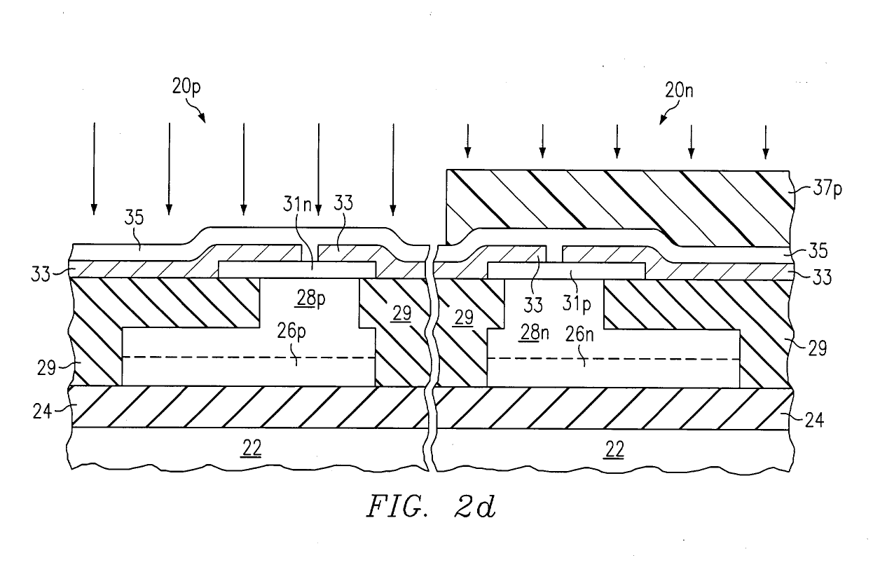

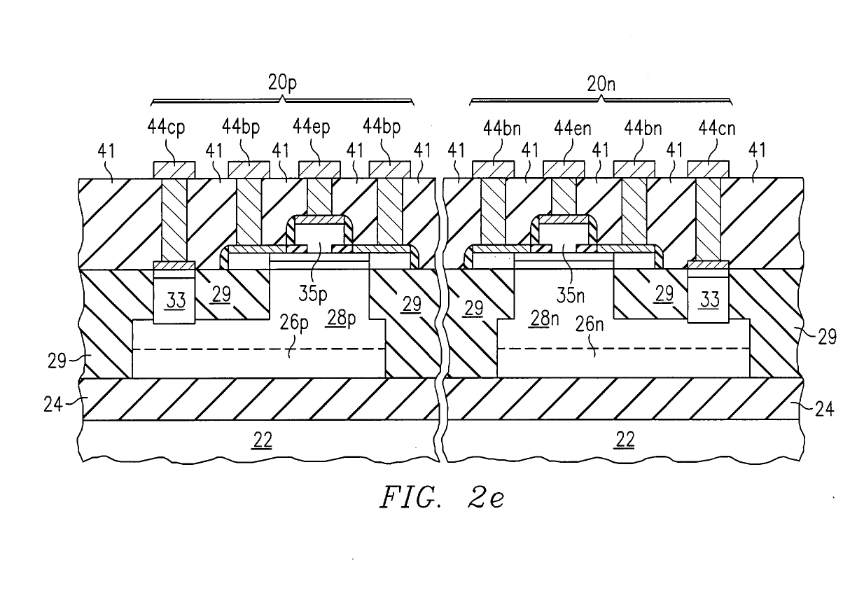

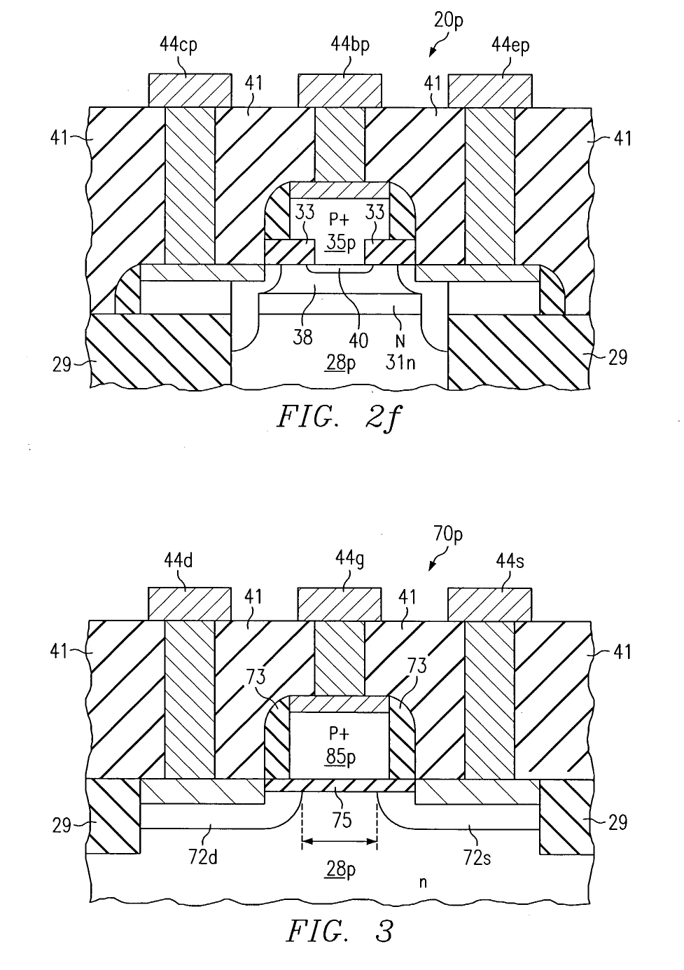

Referring now to FIGS. 2a through 2f, the construction of complementary bipolar transistors 20p, 20n according to the preferred embodiments of the invention will now be described, by way of example. In this example, transistor 20p is a PNP bipolar transistor, while transistor 20n is an NPN bipolar transistor. As will be described in further detail below, it is contemplated that the method according to these embodiments of the invention can also be applied to the manufacture of integrated circuits that include both bipolar and MOS transistors, and indeed that include bipolar and MOS transistors of both conductivity types, according to a CBiCMOS technology. Those skilled in the art will also recognize, based on this specification, that other active and passive components may also be fabricated, on the same integrated circuit, as transistors 20p, 20n.

FIG. 2a illustrates a partially-fabricated integrated circuit wafer at which transistors 20 are to be fabricated. Of course, at the point in the process flow illustrated in FIG. 2a, transistors 20p, 20n are not yet formed (i.e., necessary elements such as an emitter are not yet present), and as such reference numerals 20p, 20n refer to the locations at which transistors 20p, 20n will be formed.

Referring first to FIG. 2a, the construction of PNP transistor 20p according to the preferred embodiment of the invention will now be described in detail. The cross-section of FIG. 2a illustrates buried insulator layer 24 in place over substrate, or handle wafer, 22 in the typical manner for silicon-on-insulator (SOI) structures. Buried insulator layer 24 is typically silicon dioxide, and as such is generally referred to as buried oxide. A single-crystal silicon thin film layer including buried collector layers 26p, 26n is disposed over buried oxide layer 24. The formation of the structure of buried insulator layer 24 underlying the thin film silicon layer containing buried collector layers 26 may be accomplished by any one of a number of technologies. These technologies include the wafer bonding approach, in which two single-crystal silicon wafers are bonded to one another on either side of a silicon oxide layer, to result in single-crystal layers on either side of the insulator layer. According to another approach, referred to in the art as SIMOX, a single crystal silicon wafer is implanted with oxygen ions, so that a high concentration of oxygen is present at a selected depth within the wafer. The oxygen is thermally reacted with the silicon to form a buried oxide layer about the depth of implantation. These and other conventional techniques for fabricating an SOI structure are suitable for use in connection with this invention.

Of course, as noted above, the present invention is also applicable to bulk integrated circuits, which are not fabricated according to SOI technology but instead fabricated within a conventional silicon substrate.

In the construction of PNP transistor 20p and NPN transistor 20n, the corresponding p-type and n-type buried collector regions 26p, 26n are formed within the silicon thin film layer that overlies buried insulator 24. These regions 26p, 26n are preferably formed by way of masked implants, using photolithographically patterned hard masks, such as silicon dioxide, or a patterned layer of photoresist sufficient in thickness to block the implant. Because buried collector regions 26p, 26n are heavily-doped, to provide a low resistivity current path, the doses of these buried collector implants are relatively heavy. For example, the implant of boron for forming p-type buried collector 26p may be carried out at a dose such as 1.0E16 cm⁻², at an energy of 30 keV. An anneal to diffuse the implanted dopant, and removal of the implant masks, are then performed to complete buried collector regions 26p, 26n, as shown in FIG. 2a.

To form the active portions of eventual PNP transistor 30, epitaxial silicon is then grown over buried collector regions 26. In the structure of FIG. 2a, epitaxial regions 28p, 28n may be intrinsic silicon, or lightly-doped to the conductivity type appropriate for the collector region of the corresponding device, depending upon the design of the transistors to be formed. The doping concentration of one of epitaxial regions 28p, 28n may be set during epitaxy if desired, with the other necessarily being doped by way of a subsequent implant. Alternatively, both epitaxial regions 28p, 28n may be substantially intrinsic as formed, and then separately implanted to establish the desired collector doping concentration.

Upon completion of epitaxial layer 28, trench isolation structures 29 are formed to electrically and physically isolate the individual devices from one another. In this embodiment of the invention, as shown in FIG. 2a, trench isolation structures 29 are formed into locations of epitaxial regions 28p, 28n, and buried collector regions 26p, 26n, extending fully down to buried insulator layer 24 in some locations. For example, isolation structures 29 may be formed by first performing a masked etch of epitaxial regions 28p, 28n to a relatively shallow depth, and then performing a second masked etch through the remaining portion of epitaxial regions 28p, 28n within the etched locations until reaching buried oxide layer 24. Insulating material, such as silicon dioxide, is then deposited overall, filling the etched trenches into and through epitaxial regions 28p, 28n and buried collector regions 26p, 26n. A planarizing etchback is then preferably performed, so that the top surfaces of trench isolation structures 29 are substantially coplanar with the top of the active region of epitaxial regions 28p, 28n, as shown in FIG. 2a. Accordingly, trench isolation structure 29 of this embodiment of the invention each include both deep and shallow portions. Especially in combination with buried oxide layer 24, isolation structures 29 are effective to electrically isolate the individual transistors 20p, 20n from one another and from other devices in the integrated circuit.

Base layers 31n, 31p are also in place, in the partially-fabricated structure of FIG. 2a, overlying and in contact with epitaxial regions 28p, 28n. Base layers 31n, 31p are n-type and p-type doped silicon, preferably also formed by epitaxial growth from epitaxial regions 28p, 28n, so as to be single crystal silicon. In order to form the PNP and NPN transistors 20p, 20n, respectively, base layers 31n, 31p are of the opposite conductivity type from their respective underlying epitaxial regions 28p, 28n, which will form the collector of these devices. The doping of base layers 31n, 31p is preferably again carried out by a masked ion implant, followed by a diffusion anneal and removal of any implant mask layers.

Emitter oxide layer 33 is then formed overall. In the example shown in FIG. 2a, emitter oxide layer 33 is a deposited silicon dioxide layer, considering that it is formed over isolation structures 29 as well as base layers 31n, 31p. Alternatively, emitter oxide layer 33 may be thermally grown from base layers 31n, 31p. In either case, a photolithographic pattern and etch is performed on emitter oxide layer 33, to open emitter windows therethrough, exposing selected portions of base layers 31n, 31p at which the device emitters are to be formed, as will now be described.

The fabrication of the structure illustrated in FIG. 2a is presented by way of example only. It will be apparent to those skilled in the art having reference to this specification that many variations in the fabrication of bipolar transistors prior to formation of the emitters may alternatively be employed, in connection with this invention.

Referring now to FIG. 2b, the formation of emitter polysilicon layer 35 according to the preferred embodiments of the invention will now be described. Emitter polysilicon layer 35 according to this invention is a layer of polycrystalline silicon that is doped with a diffusion retardant. The diffusion retardant included within emitter polysilicon layer 35 according to the preferred embodiments of this invention include carbon, other carbon-bearing species such as SiGeC, and nitrogen, each of which have the property of retarding the diffusion of the common p-type dopant, boron, and of common n-type dopants such as phosphorous. It is believed that this diffusion retarding effect is due to the carbon or nitrogen occupying interstices in the silicon crystal lattice, which reduces the rate of diffusion for those dopants, such as boron and phosphorous, that diffuse interstitially.

As shown in FIG. 2b, according to the preferred embodiment of the invention, the diffusion retardant species is incorporated in a blanket fashion with the deposition of emitter polysilicon 35 for both PNP transistor 20p and NPN transistor 20n. This single deposition of polysilicon for both device types (and also, as will be described below, for the gate electrodes of MOS transistors also being formed in the integrated circuit), is contemplated to be the most efficient deposition approach for most device processes. Alternatively, if separate polysilicon deposition processes are used to deposit emitter polysilicon 35n, 35p for PNP and NPN transistors 20p, 20n, respectively, for example to permit in situ n-type and p-type doping of the polysilicon as deposited, the diffusion retardant species is preferably incorporated into both deposition steps.

For the preferred embodiment of the invention, in which a single polysilicon deposition process is performed for emitter polysilicon layer 35 for both bipolar transistors 20p, 20n, doping of the emitters for each device type is then carried out, as will now be described relative to FIGS. 2c and 2d. The ion implantation of emitter polysilicon layer 35 for NPN transistor 20n is shown in FIG. 2c. In this example, mask layer 37n is formed over the portion of emitter polysilicon 35 at the eventual location of PNP transistor 20p, by way of conventional photolithography. Mask layer 37n may be a hard mask of silicon dioxide formed by a photolithographic pattern and etch, or alternatively mask layer 37n may be formed of a photolithographically patterned photoresist. The particulars of mask layer 37n will depend upon the dose and energy of the p-type emitter implant. To form an n-type emitter for NPN transistor 20n, the implant illustrated in FIG. 5c is of an n-type dopant, such as phosphorous, antimony, or arsenic.

Similarly, referring now to FIG. 2d, emitter polysilicon 35 in the eventual location is next doped by way of a masked implant. Mask layer 37n of FIG. 2c is of course first removed, followed by the photolithographic definition of mask layer 37p, as either a hard mask or photoresist layer, as described above relative to FIG. 2c. Upon placement of mask layer 37n over emitter polysilicon 35, implant of p-type dopant, typically boron, is then performed as shown in FIG. 2d. The p-type dopant implanted in this operation will result in a p-type emitter, which is of course appropriate for PNP transistor 20p.

It is of course to be understood that the implant processes of FIGS. 2c and 2d may be reversed in order, or even performed at a stage later in the manufacturing process, such as after the patterned etch of emitter polysilicon 35.

Following the implant of emitter dopant into emitter polysilicon layer 35, conventional processing continues to complete the construction of transistors 20p, 20n, for example as shown in FIG. 2e. In this example, these conventional processes include the photolithographic patterning and etching of emitter polysilicon 35 to form emitters 35p, 35n. Additional patterned etches are performed to form collector contact structures 33, which reach from the surface of the device toward buried collector regions 26p, 26n. Emitters 35p, 35n, as well as a portion of base layers 31p, 31n, and the surface of collector contact structures 33, may be silicide-clad in the conventional manner, to provide good ohmic contact to these structures. An overlying insulator layer 41, such as boro-phospho-silicate glass (BPSG), is deposited over all, with vias etched therethrough for the formation of tungsten plugs 43. Electrical connection is then made to transistors 20p, 20n by metal conductors 44, as shown in FIG. 2e.

The completion of transistors 20p, 20n as shown in FIG. 2e is provided by way of example only. It is contemplated that many variations on this process may be envisioned by those skilled in the art having reference to this specification, and that these variations are within the scope of this invention.

At some point during the construction of transistors 20p, 20n, but after the formation and doping of emitter polysilicon layer 35, the structure is subjected to a high temperature anneal to diffuse dopant from emitters 35p, 35n into the respective bases of transistors 20p, 20n. This diffusion anneal may be performed by way of a furnace operation, in which the structure is heated to an elevated temperature for a selected time, or alternatively the diffusion anneal may be accomplished by a rapid thermal anneal (RTA). In either case, it is contemplated that the doping of polysilicon emitter 35 with a diffusion retardant such as carbon or nitrogen permits the diffusion anneal for both emitter types 35p, 35n to be performed in the same anneal. The improved diffusion control provided by the preferred embodiments of the invention therefore enables the elimination of one anneal.

FIG. 2f illustrates a portion of transistor 20p, to more clearly illustrate the reduced diffusion of dopant from polysilicon emitter 35p. As shown in FIG. 2f, lightly-doped epitaxial base region 38 is present at a portion of base layer 31n adjacent to emitter polysilicon 35p. The execution of the diffusion anneal after the heavy doping of emitter polysilicon 35p causes boron dopant to diffuse from emitter polysilicon 25p into base region 38, forming active emitter region 40 of transistor 20p. The diffusion of p-type dopant into the single-crystal n-type base region is of course necessary for reasonable bipolar transistor action. However, because of the presence of the diffusion retardant in emitter polysilicon 35p, the diffusion of boron into base region 38 occurs much more slowly, for a given set of anneal conditions, than in the absence of such diffusion retardant in emitter polysilicon 35p.

Numerous important advantages are provided by this retarded emitter diffusion, according to the preferred embodiments of the invention. The reduced diffusion rate, particularly of boron, provides additional control over the depth of emitter region 40, considering that the extent of diffusion is not as sensitive to temperature conditions as in conventional devices, simply because the diffusion rate is much slower. This retarded emitter diffusion also relieves pressure on the thermal budget of the manufacturing process, enabling the use of some high-temperature processes to optimize the formation of later structures without worry of over-diffusing the emitter dopant. In addition, the reduced diffusion rate results in better matching of similar transistors over the same integrated circuit, and over an entire wafer, as is important in many high performance analog systems.

In the complementary bipolar context, for example as shown in FIG. 2e, this invention is especially beneficial. As noted above, relative to the Background of the Invention, boron diffuses much more rapidly in silicon than do many n-type dopants. In conventional complementary devices, therefore, the depth of the emitter junction in PNP devices will be much deeper than in NPN devices, under the same diffusion anneal conditions. This differential results in poor matching of complementary device characteristics, which necessarily reduces performance of the device, unless drastic process steps such as different anneal conditions for different conductivity type dopant are taken.

However, because of the incorporation of the diffusion retardant substance into emitter polysilicon 35p, 35n, the diffusion of boron, as well as the diffusion of many n-type dopants, is greatly slowed. Because neither species now diffuses very fast, any diffusion rate difference will result in a much reduced absolute difference in emitter junction depth, and thus a much reduced difference in device performance.

It has been observed, in connection with this invention, that carbon (either elemental carbon or in the form of SiGeC) both retards the diffusion of boron, but enhances the diffusion of arsenic, which is an n-type dopant. It is believed that this effect is because arsenic diffuses substitutionally, rather than interstitially, and because it is believed that carbon occupies interstices but creates additional substitution centers. Because arsenic diffuses as much as ten times slower than boron (in the absence of carbon or another diffusion retardant), the carbon-doping of emitter polysilicon 35 will have the effect of tending to equalize the diffusion rates of arsenic and boron. Therefore, the use of this invention in connection with an n-type emitter polysilicon that is doped with arsenic and carbon will tend to equalize the emitter junction depth of both the NPN and PNP devices, further improving the matching of these devices.

FIG. 3 illustrates p-channel MOS transistor 70p, which is formed in the same integrated circuit as transistors 20p, 20n, according to another embodiment of the invention. According to this embodiment of the invention, gate polysilicon 85p is formed from the same polysilicon layer 35 used to form emitter polysilicon elements 35p, 35n. As such, gate polysilicon 85p is doped with the diffusion retardant, similarly as emitter polysilicon elements 35p, 35n. However, for transistor 70p to operate as a MOS transistor, gate oxide 75 is thermally formed prior to the deposition of gate polysilicon 85p, such that gate polysilicon 85p is insulated from well 28p (which is part of the epitaxial layer 28 described above).

As fundamental in the art, source region 72s and drain region 72d are formed in a self-aligned manner, by the ion implantation of dopant (e.g., boron) in an unmasked manner over the location of transistor 70p. Gate polysilicon 85p and its sidewall spacers 73 block this implant, separating the implanted surface of well 28p from extending up to the edge of gate polysilicon 85p (to avoid hot electron effects). However, for MOS transistor action to occur, source and drain regions 72s, 72d must extend up to the edge of gate polysilicon 85p. This “link up” is performed by way of a diffusion anneal that drives the implanted dopant under sidewall spacers 73. Using conventional BiCMOS processing, however, the strong anneal required to link up source and drain regions 72s, 72d under spacers 73 also over-diffuses dopant from emitter polysilicon, resulting in a performance and yield loss.

According to this embodiment of the invention, however, the diffusion retardant in emitter polysilicon 35 slows the outdiffusion of dopant to such an extent that it becomes safe to effect the source/drain anneal to a sufficient extent to ensure linkup of the channel, without risk of over-diffusing the emitter dopant. In addition, the doping of emitter polysilicon 35 may be performed in the same implant as the source/drain implant of regions 72s, 72d. In this way, MOS transistors such as transistor 70 are quite compatible with the fabrication of bipolar transistors according to this preferred embodiment of the invention.

Several other alternatives to the incorporation of a carbon or nitrogen species in the emitter polysilicon have also been contemplated. One such alternative embodiment involves the introduction of carbon at the interface between emitter polysilicon 35 and base layer 31 by performing a liquid rinse of the structure of FIG. 2a, using a surface-reacting carbon-containing rinse, prior to the deposition of emitter polysilicon layer 35. In this embodiment of the invention, the diffusion retardant is concentrated at the interface of interest, rather than dispersed throughout the entirety of emitter polysilicon 35. It is contemplated that similar benefits as described above would also be provided by this alternative embodiment.

Further in the alternative, GeH₄ may also be introduced into the initial portions of the deposition of the doped emitter polysilicon. The substance GeH₄ has been observed to improve device parameters such as 1/f noise and emitter resistance, thus improving the analog performance of the transistors. The introduction of GeH₄ has been observed to provide these benefits by improving the deposition process, and by assisting in breaking up any native oxides forming at the surface of base layer 31 within the emitter window through dielectric layer 31.

Still further in the alternative, it is contemplated that proper selection of the constituents of the diffusion retardant SiGeC can provide various results. For example, it is contemplated that one may change the band gap of emitter polysilicon 35 by tuning the relative concentrations of Si and Ge in the hybrid case.

It is further contemplated that the preferred embodiments of this invention may provide still further benefits. One such benefit is the destruction of the native oxides at the emitter-base interface region, improving the emitter conductivity and thus reducing the series resistance. These and other benefits will be apparent to those skilled in the art having reference to this specification.

While the present invention has been described according to its preferred embodiments, it is of course contemplated that modifications of, and alternatives to, these embodiments, such modifications and alternatives obtaining the advantages and benefits of this invention, will be apparent to those of ordinary skill in the art having reference to this specification and its drawings. It is contemplated that such modifications and alternatives are within the scope of this invention as subsequently claimed herein.

We claim:

1. A method of fabricating an integrated circuit comprising a plurality of transistors, comprising the steps of:
forming a first collector region, of a first conductivity type, at a semiconducting surface of a body;
forming a first base layer, of single-crystal silicon doped to a second conductivity type, overlying the first collector region;
forming an insulating film in contact with a surface of the first base layer, and having a window opening therethrough;
forming a layer of emitter polysilicon, doped with dopant of the first conductivity type and also doped to include a diffusion retardant, the emitter polysilicon disposed over the insulating film and in contact with the base layer through the window opening;
then heating the device to diffuse dopant from the emitter polysilicon into the underlying base region, forming an emitter region of controlled depth.

2. The method of claim 1, further comprising:
forming a buried collector region disposed under the collector region; and
forming at least one collector contact, extending from a surface of the integrated circuit toward the buried collector region.

3. The method of claim 2, further comprising:
forming a substrate comprised of a handle wafer, a buried insulator layer overlying the handle wafer, and a thin film silicon layer overlying the buried insulator layer;
and wherein the step of forming a buried collector region comprises doping selected portions of the thin film silicon layer to define at least one buried collector region.

4. The method of claim 1, wherein the diffusion retardant comprises a carbon-bearing species.

5. The method of claim 4, wherein the carbon-bearing species comprises elemental carbon.

6. The method of claim 4, wherein the carbon-bearing species comprises SiGeC.

7. The method of claim 1, wherein the diffusion retardant comprises nitrogen.

8. The method of claim 1, wherein the layer of emitter polysilicon is also doped with GeH₄.

9. The method of claim 1, further comprising:
prior to the step of forming a layer of emitter polysilicon, applying a liquid carbon-bearing rinse over the insulating film and into the window opening.

10. The method of claim 1, further comprising:
patterning the emitter polysilicon to form a first emitter of the first conductivity type.

11. The method of claim 1, further comprising:
forming a second collector region, of the second conductivity type, at the semiconducting surface;
forming a second base layer, of single-crystal silicon doped to the first conductivity type, overlying the second collector region;
wherein the insulating film is also in contact with the second base layer and has a window opening therethrough;
and wherein the step of forming a layer of emitter polysilicon comprises:
forming a layer of emitter polysilicon over the insulating film and extending into the window opening, the layer of emitter polysilicon being doped with the diffusion retardant;
doping first and second portions of the emitter polysilicon, each overlying a window opening, with dopant of the first and second conductivity types, respectively.

12. The method of claim 11, wherein the step of doping first and second portions of the emitter polysilicon comprises:
masking a first portion of the device;
imparting dopant of a second conductivity type into the exposed second portion of the emitter polysilicon;
masking the second portion of the device; and
imparting dopant of the first conductivity type into the exposed first portion of the emitter polysilicon.

13. The method of claim 12, wherein the dopant of the second conductivity type comprises arsenic;
and wherein the dopant of the first conductivity type comprises boron.

14. The method of claim 12, wherein the dopant of the second conductivity type comprises phosphorous;
and wherein the dopant of the first conductivity type comprises boron.

15. The method of claim 1, wherein the heating step comprises placing the device containing the integrated circuit into a furnace at an elevated temperature for a selected time.

16. The method of claim 1, wherein the heating step comprises a rapid thermal anneal.

17. An integrated circuit, comprising:
a first bipolar transistor, comprising:
a first collector region, of a first conductivity type, at a semiconducting surface of a body;
a first base layer, formed of single-crystal silicon doped to a second conductivity type, disposed over the first collector region;
a first insulating film disposed over the first base layer, having a first window opening therethrough; and
a first polysilicon emitter, doped with dopant of the first conductivity type and also doped with a diffusion retardant, disposed over the first insulating film and extending into the first window opening to contact the first base layer;
wherein the first base layer includes a region into which dopant from the first polysilicon emitter has diffused.

18. The integrated circuit of claim 17, wherein the first bipolar transistor further comprises:
a first buried collector region disposed under the first collector region;
a first collector contact, extending from a surface of the integrated circuit toward the first buried collector region.

19. The integrated circuit of claim 18, further comprising:
a handle wafer; and
a buried insulator layer, disposed between the handle wafer and the first buried collector region.

20. The integrated circuit of claim 17, wherein the diffusion retardant comprises a carbon-bearing species.

21. The integrated circuit of claim 20, wherein the carbon-bearing species comprises elemental carbon.

22. The integrated circuit of claim 20, wherein the carbon-bearing species comprises SiGeC.

23. The integrated circuit of claim 17, wherein the diffusion retardant comprises nitrogen.

24. The integrated circuit of claim 17, wherein the first polysilicon emitter is also doped with GeH₄.

25. The integrated circuit of claim 17, further comprising:
a second bipolar transistor, comprising:
a second collector region, of the second conductivity type, at the semiconducting surface of the body;
a second base layer, formed of single-crystal silicon doped to the first conductivity type, disposed over the second collector region;
a second insulating film disposed over the second base layer, having a second window opening therethrough; and
a second polysilicon emitter, doped with dopant of the second conductivity type and also doped with the diffusion retardant, disposed over the second insulating film and extending into a second window opening to contact the second base layer;
wherein the second base layer includes a region into which dopant from the second polysilicon emitter has diffused.

26. The integrated circuit of claim 25, wherein the dopant of the second conductivity type comprises arsenic;
and wherein the dopant of the first conductivity type comprises boron.

27. The integrated circuit of claim 25, wherein the dopant of the second conductivity type comprises phosphorous;
and wherein the dopant of the first conductivity type comprises boron.
